(19) United States
(12) Patent Application Publication
(10) Pub. No.: US 2019/0094434 A1
(43) Pub. Date: Mar. 28, 2019

(54) DISPLAY MODULE AND METHOD OF MANUFACTURING THE SAME, DISPLAY DEVICE

(71) Applicants: BOE TECHNOLOGY GROUP CO., LTD., Beijing (CN); ORDOS YUANSHENG OPTOELECTRONICS CO., LTD., Ordos (CN)

(72) Inventors: Jin XU, Beijing (CN); Ning AO, Beijing (CN); Jianqiang WANG, Beijing (CN); Dezhi WANG, Beijing (CN); Nini BAI, Beijing (CN); Qi LIU, Beijing (CN); Guoping ZHANG, Beijing (CN)

(21) Appl. No.: 16/112,018

(22) Filed: Aug. 24, 2018

(30) Foreign Application Priority Data
Sep. 22, 2017 (CN) 201710872735.7

(51) Int. Cl. G02B 5/30; G02F 1/1335; H01L 51/52

(52) U.S. Cl. CPC G02B 5/3041; H01L 51/5281; G02F 1/133528

(57) ABSTRACT

A display module includes a display panel and a transmittance adjusting structure disposed on a light exit side of the display panel. A transmittance of the transmittance adjusting structure varies regionally in accordance with a regional distribution law of a display luminance of the display panel.

### CROSS-REFERENCE TO RELATED APPLICATION

This application claims priority to Chinese Patent Application No. 201710872735.7, filed on Sep. 22, 2017, titled “A DISPLAY MODULE AND METHOD OF MANUFACTURING THE SAME, DISPLAY DEVICE”, which is incorporated herein by reference in its entirety.

### TECHNICAL FIELD

The present disclosure relates to the field of display technologies, and in particular, to a display module and a method of manufacturing the same, and a display device.

### BACKGROUND

With the development of display technologies, customers are setting increasingly high requirements for display products. Luminance, as the most intuitive performance presented to users, is often an important indicator in customers' requirements for a product.

### SUMMARY

Some embodiments of the present disclosure provide a display module, which comprises a display panel and a transmittance adjusting structure disposed on a light exit side of the display panel. A transmittance of the transmittance adjusting structure varies regionally in accordance with a regional distribution law of a display luminance of the display panel.

In some embodiments, the transmittance adjusting structure comprises at least one first polarizer, and each first polarizer has a regionally-varying transmittance.

In some embodiments, the transmittance adjusting structure includes a single first polarizer, and the first polarizer comprises a polarizing film.

In some embodiments, the transmittance adjusting structure comprises a single first polarizer, and the first polarizer comprises two layers of polarizing films stacked one on another.

In some embodiments, the transmittance adjusting structure comprises two first polarizers stacked one on another, and each of the two first polarizers comprises a polarizing film.

In some embodiments, the transmittance adjusting structure comprises a second polarizer having a uniform transmittance and a film layer having a regionally-varying transmittance, and the film layer and the second polarizer are stacked one on another.

In some embodiments, the display panel comprises an array substrate and an encapsulating substrate, the array substrate comprises OLED components, and each OLED component is disposed in a corresponding one of pixel units.

In some embodiments, the OLED components are of a top light-emitting type; the transmittance adjusting structure is disposed on a side of the encapsulating substrate facing the array substrate, or disposed on a side of the encapsulating substrate facing away from the array substrate.

In some embodiments, the OLED components are of a bottom light-emitting type; the transmittance adjusting structure is disposed on a side of the array substrate facing away from the encapsulating substrate.

In some embodiments, the display panel comprises an array substrate, an assembling substrate, and a liquid crystal layer disposed therebetween.

In some embodiments, the display panel comprises an array substrate, an assembling substrate, and a liquid crystal layer disposed therebetween. Based on this, in the case where the transmittance adjusting structure comprises a first polarizer or a second polarizer, the transmittance adjusting structure is disposed on a side of the assembling substrate facing away from the array substrate; and the display module further comprises a lower polarizer disposed on a side of the array substrate facing away from the assembling substrate, and the lower polarizer has a uniform transmittance.

Some embodiments of the present disclosure provide a display device, which comprises the display module described above.

Some embodiments of the present disclosure provide a method of manufacturing the display module described above, which comprises: manufacturing a display panel; and forming a transmittance adjusting structure on a light exit side of the display panel. The transmittance of the transmittance adjusting structure varies regionally in accordance with a regional distribution law of a display luminance of the display panel.

In some embodiments, forming the transmittance adjusting structure on the light exit side of the display panel comprises: manufacturing at least one first polarizer each having a regionally-varying transmittance, and attaching the at least one first polarizer to the light exit side of the display panel.

In some embodiments, forming the transmittance adjusting structure on the light exit side of the display panel comprises: manufacturing a second polarizer having a uniform transmittance and a film layer having a regionally-varying transmittance that is in contact with the second polarizer and is disposed on one side of the second polarizer, and attaching the second polarizer and the film layer to the light exit side of the display panel.

In some embodiments, manufacturing the at least one first polarizer each having a regionally-varying transmittance comprises: manufacturing a single first polarizer. The first polarizer comprises a polarizing film.

In some other embodiments, manufacturing the at least one first polarizer each having a regionally-varying transmittance comprises: manufacturing a single first polarizer. The first polarizer comprises two layers of polarizing films that are stacked one on another.

In other embodiments, manufacturing the at least one first polarizer each having a regionally-varying transmittance comprises: manufacturing two first polarizers that are stacked one on another. Each of the two first polarizers comprises a polarizing film.

### BRIEF DESCRIPTION OF THE DRAWINGS

In order to describe technical solutions in embodiments of the present disclosure more clearly, the accompanying drawings to be used in the description of embodiments will be introduced briefly. Obviously, the accompanying drawings to be described below are merely some embodiments of the present disclosure, and a person of ordinary skill in the art can obtain other drawings according to those drawings without paying any creative effort.

FIG. 1 is a schematic diagram of a display module according to some embodiments of the present disclosure;

FIG. 2 is a schematic diagram of an array substrate in a display panel according to some embodiments of the present disclosure;

FIG. 3a is a schematic diagram of a transmittance adjusting structure according to some embodiments of the present disclosure;

FIG. 3b is a schematic diagram of another transmittance adjusting structure according to some embodiments of the present disclosure;

FIG. 4a is a schematic diagram of a first polarizer according to some embodiments of the present disclosure;

FIG. 4b is a schematic diagram of another first polarizer according to some embodiments of the present disclosure;

FIG. 5 is a schematic diagram of another transmittance adjusting structure according to some embodiments of the present disclosure;

FIG. 6 is a schematic diagram showing that 9 points are selected to carry out luminance test on a display panel according to some embodiments of the present disclosure;

FIG. 7 is a schematic diagram showing that corresponding 9 points are selected to carry out luminance test after attaching a polarizer with a uniform transmittance to a display panel according to some embodiments of the present disclosure;

FIG. 8 is a schematic diagram showing that corresponding 9 points are selected to carry out luminance test after attaching a polarizer with a varying transmittance to a display panel according to some embodiments of the present disclosure;

FIG. 9 is a schematic diagram of another display module according to some embodiments of the present disclosure;

FIG. 10 is a schematic diagram of yet another display module according to some embodiments of the present disclosure;

FIG. 11 is a schematic diagram of yet another display module according to some embodiments of the present disclosure;

FIG. 12 is a graph showing a corresponding relationship between a luminance and a voltage of a VSS terminal according to some embodiments of the present disclosure;

FIG. 13 is a schematic diagram of yet another display module according to some embodiments of the present disclosure; and

FIG. 14 is a schematic flow chart of a method of manufacturing a display module according to some embodiments of the present disclosure.

### DETAILED DESCRIPTION

The technical solutions in embodiments of the present disclosure will be described clearly and completely below with reference to the accompanying drawings. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

In the related art, due to various factors such as process uniformity and current decay in the circuit of the display panel, there is usually a problem of uneven display luminance.

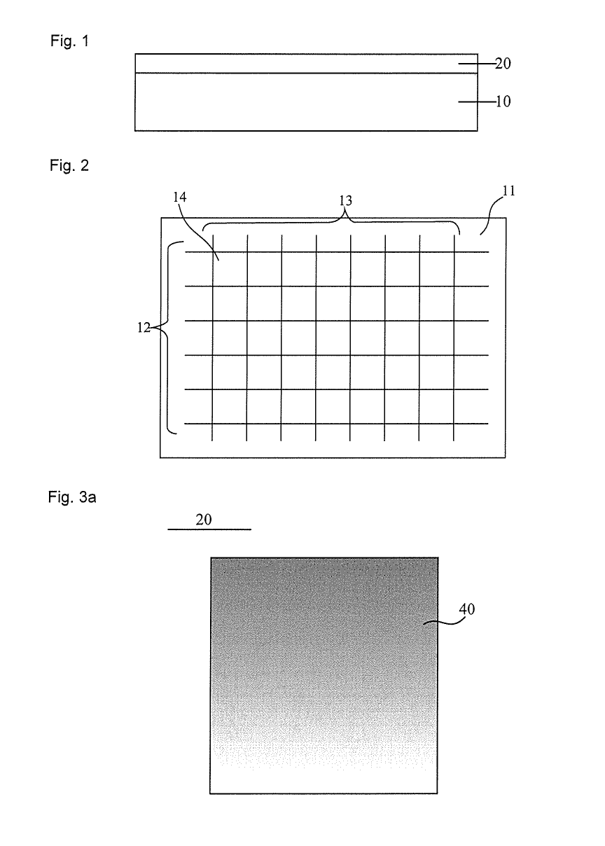

For this problem, some embodiments of the present disclosure provide a display module. As shown in FIG. 1, the display module includes a display panel 10, and a transmittance adjusting structure 20 disposed on a light exit side of the display panel 10. A transmittance of the transmittance adjusting structure 20 varies regionally in accordance with a regional distribution law of a display luminance of the display panel 10.

In some embodiments, the display panel includes an array substrate, and as shown in FIG. 2, the array substrate 11 includes gate lines 12 and data lines 13. The gate lines 12 and the data lines 13 intersect to define pixel units 14. The data lines 13 are connected to a source driving circuit, and the gate lines 12 are connected to a gate driving circuit. The gate driving circuit includes a plurality of shift registers, and the main function of the gate driving circuit is to scan the gate lines 12 line by line. The source driving circuit includes a plurality of digital-to-analog converters, and each digital-to-analog converter corresponds to a data line. The main function of the source driving circuit is to use Gamma voltages to convert signals generated by a Timing Controller (T-con) into analog signals corresponding to grayscale voltages respectively, and input the analog signals to the data lines 13, so as to drive the display panel 10 for display.

The gate driving circuit is for example directly manufactured on the array substrate 11. The gate driving circuit is also for example integrated in a gate driver integrated circuit (IC), with the gate driver IC bonded to the array substrate 11. Similarly, the source driving circuit is for example directly manufactured on the array substrate 11. The source driving circuit is also for example integrated in a source driver IC, with the source driver IC bonded to the array substrate 11.

The Gamma voltage is programmed into the source driver IC before the display panel leaves the factory. The programming process is usually as below: assuming that the display panel has a uniform luminance at different gray levels, detecting a luminance at a center of the display panel with a luminance test probe, and adjusting the Gamma voltage to the required luminance and chromaticity coordinates.

However, since the programming process is only based on the luminance at the center of the display panel, it is impossible to take a luminance distribution of the entire display panel into consideration. Moreover, since there is IR drop in a data line 13, a voltage and a current in the data line 13 will gradually decrease from one end of the data line 13 connected to the source driving circuit to another end, and there is a significant difference in current especially between two ends of the data line 13, which results in poor luminance uniformity of the display panel 10 as a whole. Visually, there is such a display effect that luminance is high at a position close to the source driving circuit and is low at a position away from the source driving circuit.

Of course, in addition to the IR drop in the data line 13, many other factors such as process uniformity will also cause poor luminance uniformity. However, as long as the regional distribution of the luminance of the display panel 10 is regular, the luminance uniformity may always be improved through the provision of the transmittance adjusting structure 20.

It will be understood by those skilled in the art that before manufacturing the transmittance adjusting structure 20, a regional distribution law of each type of display panel 10 is obtained according to a luminance non-uniformity thereof during the light-on test.

Based on this, according to the regional distribution law of the luminance of the display panel 10, the display panel 10 can be divided into regions. A regional division of the display panel 10 is in line with the regional distribution of the luminance of the display panel 10, that is, the luminance uniformity is high inside each region, and there is a significant difference in the luminance in different regions.

On this basis, when manufacturing the transmittance adjusting structure 20, the transmittance adjusting structure 20 is divided into a plurality of regions according to the regional division of the display panel 10, and the transmittance of each region is set separately.

The principle of regional division of the transmittance adjusting structure 20 is: in the case where the transmittance adjusting structure 20 is disposed on the display panel 10, the regions of the transmittance adjusting structure 20 are in one-to-one correspondence with and completely overlap divided regions of the display panel 10. The principle of setting a transmittance for each region of the transmittance adjusting structure 20 is: according to the regional division of the display panel 10, if a luminance of a certain region of the display panel 10 is low, the transmittance of a corresponding region of the transmittance adjusting structure 20 will be set high; if the luminance of a certain region of the display panel 10 is high, the transmittance of a corresponding region of the transmittance adjusting structure 20 will be set low, so that after the adjustment by the transmittance adjusting structure 20, the luminance uniformity of light emitted from various regions of the display panel 10 is improved.

In the display module provided by the embodiments of the present disclosure, the transmittance adjusting structure 20 is provided on a light exit side of the display panel 10, and the transmittance of the transmittance adjusting structure 10 varies regionally in accordance with a regional distribution law of a display luminance of the display panel 10. In the case where the regional distribution of the luminance of the display panel 10 is regular, by setting the transmittance of each region of the transmittance adjusting structure 20 properly, the luminance of light emitted from the display module may be made more uniform.

In addition, the transmittance of each region of the transmittance adjusting structure 20 is set according to the luminance of a corresponding region of the display panel 10 in for example the light-on test, and the display panel 10 displays a high grayscale image during the light-on test, so that the transmittance adjusting structure 20 may improve the luminance uniformity of light emitted from the display module at high gray levels. Moreover, the provision of the transmittance adjusting structure 20 may also improve the luminance uniformity of the display panel 10 at extremely low gray levels (for example, L0 grayscale). Therefore, even if for some products, the problem of luminance non-uniformity is more serious at extremely low gray levels, the luminance uniformity may also be improved through the provision of a transmittance adjusting structure 20.

In some embodiments, the transmittance adjusting structure 20 is directly manufactured on a light exit side of the display panel 10. In some other embodiments, the transmittance adjusting structure 20 is separately manufactured and then attached to a light exit side of the display panel 10.

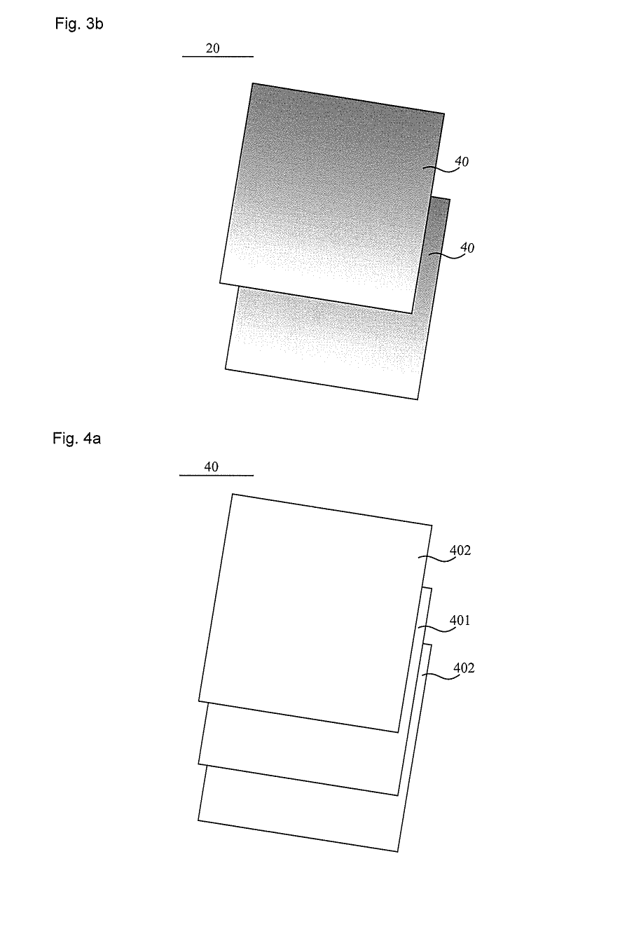

In some embodiments, as shown in FIGS. 3a and 3b, the transmittance adjusting structure 20 includes at least one first polarizer 40 each having a regionally-varying transmittance.

Since each of the at least one polarizer has a thin thickness, and it is technically easy to achieve different transmittances in different regions of a polarizer, the at least one polarizer is used as the transmittance adjusting structure 20.

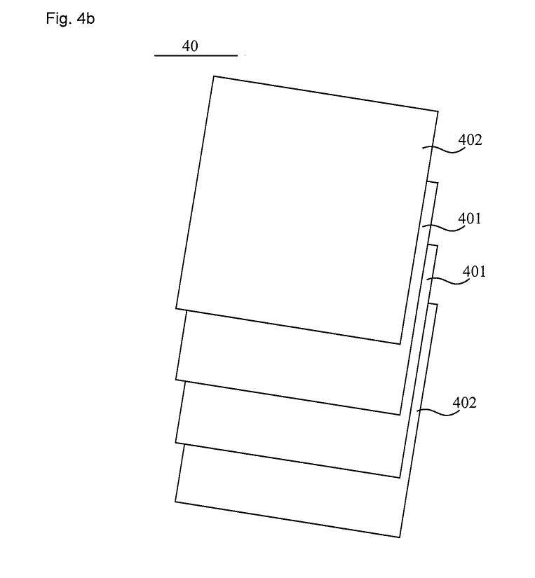

In some embodiments, as shown in FIGS. 3a and 4a, the transmittance adjusting structure 20 includes a single first polarizer 40, and the first polarizer 40 includes a polarizing film 401. In some embodiments, the first polarizer 40 further includes protective films 402 disposed on both sides of the polarizing film 401.

In some other embodiments, as shown in FIGS. 3a and 4b, the transmittance adjusting structure 20 includes a single first polarizer 40, and the first polarizer 40 includes two layers of polarizing films 401 stacked one on another. In some embodiments, the transmittance adjusting structure 20 further includes a protective film provided between the two layers of polarizing films 401.

It will be understood that, only the transmittance of the polarizing film 401 varies regionally in the first polarizer 40. When manufacturing the polarizing film, the transmittance of different regions of the polarizing film is controlled according to requirements on the transmittance of each region. For example, when using a stretching technique to manufacture a polarizing film, it will be assured that different regions have different transmittances by controlling the stretching technique.

In the case where the regional division of luminance is rather simple in the display panel 10, and it is technically possible to make a polarizing film 401 have a corresponding transmittance in each of corresponding regions, then the first polarizer 40 includes for example only one polarizing film 401. In the case where the regional division of the luminance is relatively complicated in the display panel 10, and it is technically impossible to make a polarizing film 401 have a corresponding transmittance in each of corresponding regions, then the first polarizer 40 includes two layers of polarizing films 401. Each of the polarizing films 401 is divided into multiple regions, and the transmittance of each region is set properly, so that the overall transmittance of the first polarizer 40 varies regionally, and the regions are in one-to-one correspondence with the regions of the display panel 10 divided according to luminance.

It will be noted that, in the case where the first polarizer 40 includes two layers of polarizing films 401 stacked one on another, a polarizing film 401 having a high transmittance will be used in order to prevent an overall transmittance of the first polarizer 40 from being too low.

In some other embodiments, as shown in FIG. 3b, the transmittance adjusting structure 20 includes two first polarizers 40, and the two first polarizers 40 are stacked one on another. Each of the first polarizers 40 includes a polarizing film 401 (as shown in FIG. 4a).

The two first polarizers 40 are manufactured separately. Each of the first polarizers 40 is divided into regions, and the transmittance of each region is set properly, so that the overall transmittance of the two first polarizers 40 varies regionally, and the regions of the two first polarizers 40 are in one-to-one correspondence with the regions of the display panel 10 divided according to luminance.

It will be noted that in the case where the transmittance adjusting structure 20 includes two first polarizers 40, a first polarizer 40 having a high transmittance will be used in order to prevent the overall transmittance of the two first polarizers 40 from being too low.

Compared with manufacturing a first polarizer 40 including two layers of polarizing films 401 stacked one on another, it is technically easier to manufacture a first polarizer 40 including one polarizing film 401.

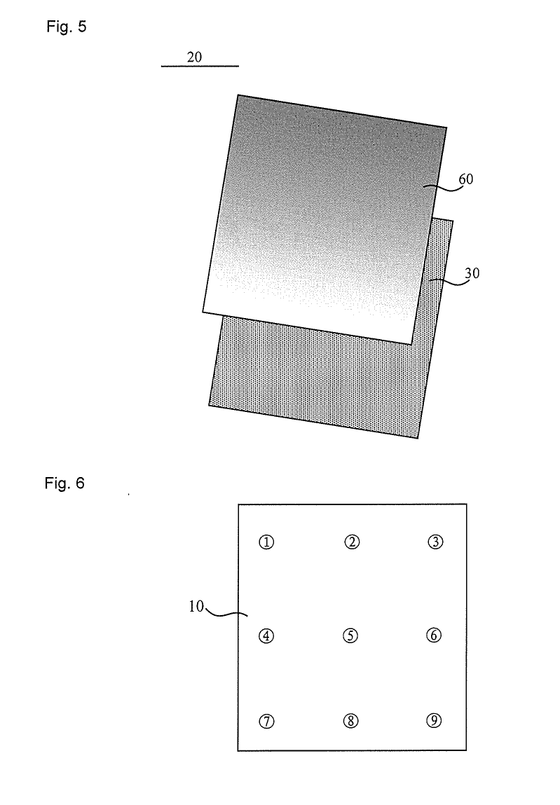

In some embodiments, as shown in FIG. 5, the transmittance adjusting structure 20 includes a single second polarizer 30 having a uniform transmittance and a film layer 60 having a regionally-varying transmittance. The film layer 60 and the second polarizer 30 are stacked one on another.

For example, the transmittance adjusting structure 20 is manufactured based on the second polarizer 30 having a uniform transmittance. In some embodiments, the method for manufacturing the second polarizer 30 having a uniform transmittance includes: laminating one roll of polarizer having a uniform transmittance at a time, and cutting the roll of polarizer into corresponding sizes as needed so as to obtain the second polarizers 60 each having a uniform transmittance. Then, a film layer 60 having a regionally-varying transmittance is manufactured on the second polarizer 30 of a corresponding size, so that the finished transmittance adjusting structure 20 has different transmittances in different regions. In some embodiments, the film layer 60 having a regionally-varying transmittance is manufactured through ink printing.

The effect of improved luminance uniformity of the display panel will be described below with specific data.

Taking an FHD (Full High Definition) display panel 10 as an example, as shown in FIG. 6, the following test results are obtained after carrying out luminance and chromaticity coordinates tests on points 1 to 9 on the display panel 10:

luminance of point 1=846.2 nit, and chromaticity coordinates of point 1 are (0.3010, 0.3118);

luminance of point 2 L₂=831.6 nit, and chromaticity coordinates of point 2 are (0.2998, 0.3109);

luminance of point 3 L₃=837.9 nit, and chromaticity coordinates of point 3 are (0.2996, 0.3104);

luminance of point 4 L₄=795.9 nit, and chromaticity coordinates of point 4 are (0.3008, 0.3142);

luminance of point 5 L₅=792.5 nit, and chromaticity coordinates of point 5 are (0.2999, 0.3147);

luminance of point 6 L₆=796.2 nit, and chromaticity coordinates of point 6 are (0.2988, 0.3122);

luminance of point 7 L₇=779.9 nit, and chromaticity coordinates of point 7 are (0.3026, 0.3171);

luminance of point 8 L₈=778.6 nit, and chromaticity coordinates of point 8 are (0.3017, 0.3174);

luminance of point 9 L₉=780.3 nit, and chromaticity coordinates of point 9 are (0.2986, 0.3146).

From this, it can be seen that the maximum luminance Lₘₐₓ=846.2 nit, and the minimum luminance Lₘᵢₙ=778.6 nit. Based on this, the uniformity=Lₘᵢₙ/Lₘₐₓ=92%.

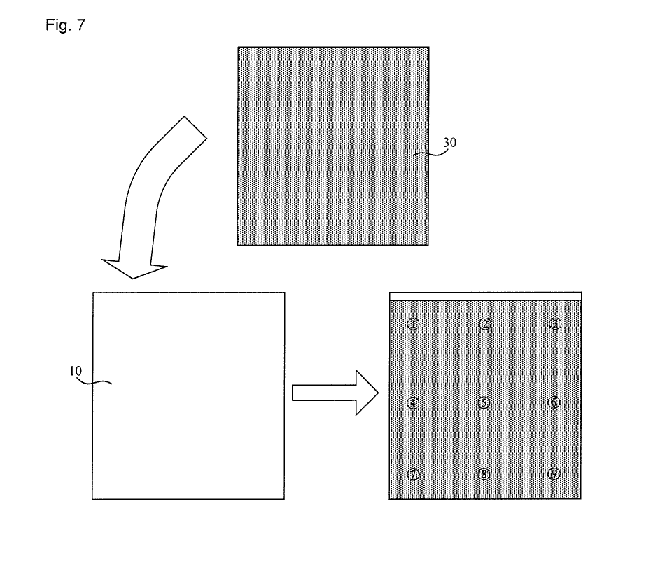

As shown in FIG. 7, the second polarizer 30 having a uniform transmittance (transmittance: 46.8%) is attached to a light exit side of the display panel 10, and the following test results are obtained after carrying out luminance and chromaticity coordinates tests on points 1 to 9:
luminance of point 1 L₁=396.0 nit, and chromaticity coordinates of point 1 are (0.3010, 0.3118);
luminance of point 2 L₂=389.2 nit, and chromaticity coordinates of point 2 are (0.2998, 0.3109);
luminance of point 3 L₃=391.7 nit, and chromaticity coordinates of point 3 are (0.2996, 0.3104);
luminance of point 4 L₄=372.5 nit, and chromaticity coordinates of point 4 are (0.3008, 0.3142);
luminance of point 5 L₅=370.9 nit, and chromaticity coordinates of point 5 are (0.2999, 0.3147);
luminance of point 6 L₆=372.6 nit, and chromaticity coordinates of point 6 are (0.2988, 0.3122);
luminance of point 7 L₇=365.0 nit, and chromaticity coordinates of point 7 are (0.3026, 0.3171);
luminance of point 8 L₈=364.4 nit, and chromaticity coordinates of point 8 are (0.3017, 0.3174);
luminance of point 9 L₉=365.2 nit, and chromaticity coordinates of point 9 are (0.2986, 0.3146).

From this, it can be seen that the maximum luminance Lₘₐₓ=396.0 nit, and the minimum luminance Lₘᵢₙ=364.4 nit. Based on this, the uniformity=Lₘᵢₙ/Lₘₐₓ=92%.

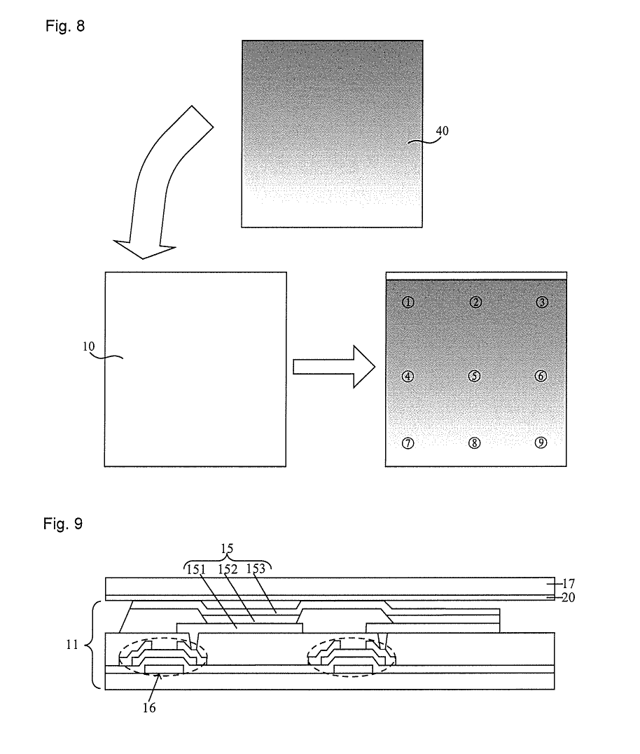

Taking an example in which the transmittance adjusting structure 20 includes a single first polarizer 40, and the first polarizer 40 includes a single polarizing film 401, the display panel 10 may be divided into three regions, that is, upper, middle and lower regions, according to the above luminance variation of the display panel 10. Correspondingly, the first polarizer 40 is also divided into such three regions, and the transmittances of the upper, middle and lower regions of the first polarizer 40 are 45%, 45.9%, and 46.8%, respectively. Based on this, as shown in FIG. 8, the first polarizer 40 is attached to a light exit side of the display panel 10, the following test results are obtained after carrying out luminance and chromaticity coordinates tests on points 1 to 9:
luminance of point 1 L₁=380.8 nit, and chromaticity coordinates of point 1 are (0.3010, 0.3118);
luminance of point 2 L₂=374.2 nit, and chromaticity coordinates of point 2 are (0.2998, 0.3109);
luminance of point 3 L₃=376.6 nit, and chromaticity coordinates of point 3 are (0.2996, 0.3104);
luminance of point 4 L₄=365.3 nit, and chromaticity coordinates of point 4 are (0.3008, 0.3142);
luminance of point 5 L₅=363.8 nit, and chromaticity coordinates of point 5 are (0.2999, 0.3147);
luminance of point 6 L₆=365.4 nit, and chromaticity coordinates of point 6 are (0.2988, 0.3122);
luminance of point 7 L₇=365.0 nit, and chromaticity coordinates of point 7 are (0.3026, 0.3171);
luminance of point 8 L₈=364.4 nit, and chromaticity coordinates of point 8 are (0.3017, 0.3174);
luminance of point 9 L₉=365.2 nit, and chromaticity coordinates of point 9 are (0.2986, 0.3146).

From this, it can be seen that the maximum luminance Lₘₐₓ=380.8 nit, and the minimum luminance Lₘᵢₙ=363.8 nit. Based on this, the uniformity=Lₘᵢₙ/Lₘₐₓ=96%.

Of course, the effect of improved uniformity may also be achieved in the case where the transmittance adjusting structure 20 includes a single first polarizer 40, and the first polarizer 40 includes two layers of polarizing films 401 stacked one on another, or in the case where the transmittance adjusting structure 20 includes two first polarizers 40, and each of the two first polarizers 40 includes a polarizing film 401. In addition, the effect of improved uniformity may still be achieved in the case where the transmittance adjusting structure 20 includes a second polarizer 30 having a uniform transmittance and a film layer 60 having a regionally-varying transmittance.

It can be seen from the description of the three situations above that, the luminance uniformity may be improved in the case where a transmittance adjusting structure 20 is provided.

In some embodiments, as shown in FIGS. 9-11, the display panel 10 includes an array substrate 11 and an encapsulating substrate 17. The array substrate 11 includes OLED (Organic Light-Emitting Diode) components 15, and each OLED component is disposed in a corresponding one of the pixel units 14.

That is, the display panel 10 is an OLED display panel. For an OLED display panel of an active-matrix driving type, each of the pixel units 14 of the array substrate 11 further includes a driving circuit, and the driving circuit includes a driving transistor 16.

The OLED components 15 include an anode 151, an organic material functional layer 152, and a cathode 153.

The display panel 10 is classified into a single-sided light-emitting type and a double-sided light-emitting type depending on materials of the anode 151 and the cathode 153. That is, in the case where one of the anode 151 and the cathode 153 is opaque, the display panel 10 is of a single-sided light-emitting type, and in the case where both the anode 151 and the cathode 153 are transparent, the display panel 10 is of a double-sided light-emitting type.

The single-sided light-emitting type display panel 10 is further classified into a top light-emitting type and a bottom light-emitting type depending on the materials of the anode 151 and the cathode 153. In some embodiments, the display panel is referred to as a bottom light-emitting type display panel in the case where the anode 151 is disposed close to a substrate of the array substrate 11, the cathode 153 is disposed away from the substrate of the array substrate 11, and the anode 151 is transparent and the cathode 153 is opaque. The display panel is referred to as a top light-emitting type display panel in the case where the anode 151 is opaque and the cathode 153 is transparent. Of course, in some other embodiments, in the case where positions of the anode 151 and the cathode 153 are interchanged, a corresponding light-emitting type is also interchanged.

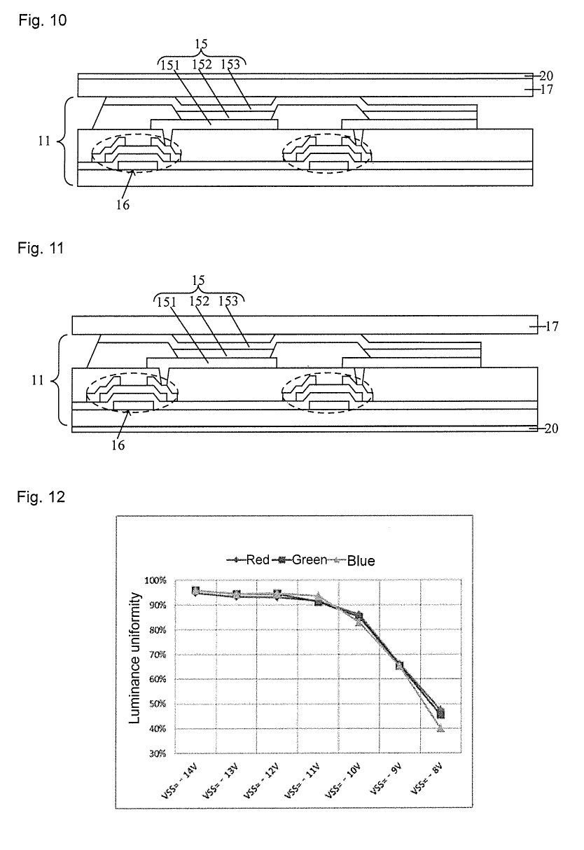

For the top light-emitting type, in some embodiments, as shown in FIG. 9, the transmittance adjusting structure 20 is disposed on a side of the encapsulating substrate 17 facing the array substrate 11. In some other embodiments, as shown in FIG. 10, the transmittance adjusting structure 20 is disposed on a side of the encapsulating substrate 17 facing away from the array substrate 11.

For the bottom light-emitting type, in some embodiments, as shown in FIG. 11, the transmittance adjusting structure 20 is disposed on a side of the array substrate 11 facing away from the encapsulating substrate 17.

Of course, for the double-sided light-emitting type, a position of the transmittance adjusting structure 20 may be set with reference to the positions of the transmittance adjusting structure 20 in the top light-emitting type and bottom light-emitting type display panels described above, and it will not be repeated here.

In the case where the display panel 10 is an OLED display panel, the display module provided by the present disclosure has the advantages of being lighter, thinner and power-saving, having high contrast, large viewing angle, high luminous efficiency, wide applicable temperature range, and short response time, and being able to be manufactured on a flexible substrate.

It will be noted that, for the OLED display panel, due to the existence of a threshold voltage, the non-uniformity of the threshold voltage may also cause a difference in luminance in some products. In addition, a difference in a luminous efficiency of light-emitting layers and line loss in the driving circuit may also cause a difference in luminance.

However, as described above, no matter what reason causes the luminance to be non-uniform, as long as the regional distribution of the luminance of the display panel 10 is regular, the luminance uniformity may be improved through the provision of a transmittance adjusting structure 20.

In addition, for the OLED display panel, each of the pixel units 14 includes a driving circuit, and the driving circuit is connected to the VSS terminal (low voltage terminal). The more negative the voltage at the VSS terminal, the higher the luminance uniformity of the OLED display panel (as shown in FIG. 12). However, when the voltage of the VSS terminal is turned in a negative direction, power consumption is increased. In the embodiments of the present disclosure, since a transmittance adjusting structure 20 is provided to improve the luminance uniformity, when debugging the voltage at the VSS terminal, it is not necessary to debug the VSS very small for luminance uniformity, leaving a larger operational margin for signal debugging.

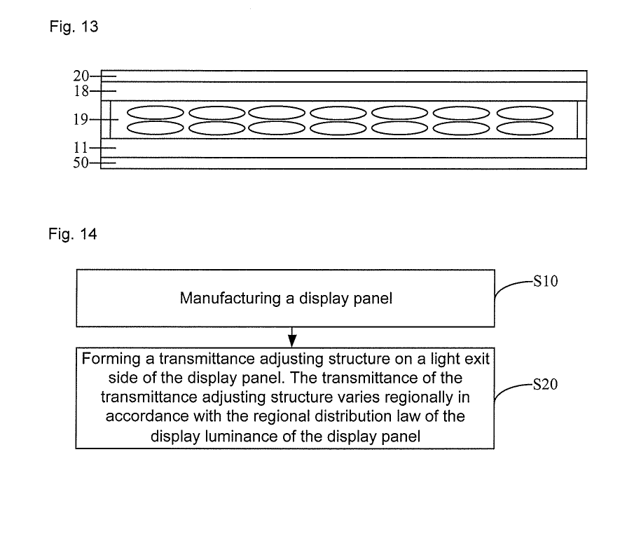

In some embodiments, as shown in FIG. 13, the display panel 10 includes an array substrate 11, an assembling substrate 18, and a liquid crystal layer 19 disposed therebetween.

That is, the display panel 10 is a liquid crystal display panel.

In some embodiments, in the case where the transmittance adjusting structure 20 includes a first polarizer 40 or a second polarizer 30, as shown in FIG. 13, the transmittance adjusting structure 20 is disposed on a side of the assembling substrate 18 facing away from the array substrate 11. Based on this, the display module further includes a lower polarizer 50 disposed on a side of the array substrate 11 facing away from the assembling substrate 18, and the lower polarizer 50 has a uniform transmittance.

It will be noted that, for the liquid crystal display device, non-uniformity of the backlight may also cause a difference in the luminance of the display panel. However, as described above, no matter what reason causes the luminance to be non-uniform, as long as the regional distribution of the luminance of the display panel 10 is regular, the luminance uniformity may be improved through the provision of a transmittance adjusting structure 20.

Some embodiments of the present disclosure provide a display device including the display module described above.

In some embodiments, the display device is rectangular in shape. In some embodiments, the display device is in other regular shapes, such as circular, elliptical, or the like.

The display device is for example a television, a display, a notebook computer, a tablet computer, a smart phone, a watch, a wristband, an electronic photo album, or the like.

Some embodiments of the present disclosure provide a method of manufacturing a display module, such as the display module provided by the above embodiments. As shown in FIG. 4, the method includes:

S10: Manufacturing a display panel 10, as shown in FIG. 1;

S20: Forming a transmittance adjusting structure 20 on a light exit side of the display panel 10, as shown in FIG. 1. The transmittance of the transmittance adjusting structure 20 varies regionally in accordance with the regional distribution law of the display luminance of the display panel 10.

The description of the display panel 10 and the transmittance adjusting structure 20 above is also applicable to the display panel 10 and the transmittance adjusting structure 20 involved in the method of manufacturing the display panel, and details are not described herein again.

In the method of manufacturing the display module provided by the embodiments of the present disclosure, a transmittance adjusting structure 20 is provided on a light exit side of the display panel 10, and the transmittance of the transmittance adjusting structure 10 is made to vary regionally in accordance with the regional distribution law of the display luminance of the display panel 10. In the case where the regional distribution of the luminance of the display panel 10 is regular, by setting the transmittance of each region of the transmittance adjusting structure 20 properly, the light emitted from the display module may be made more uniform, and the problem of non-uniform display luminance at extremely low gray levels may be improved.

In some embodiments, forming a transmittance adjusting structure 20 on the light exit side of the display panel 10 includes: manufacturing at least one first polarizer 40 each having a regionally-varying transmittance, and attaching the at least one first polarizer 40 to the light exit side of the display panel 10.

In this case, in some embodiments, manufacturing the at least one first polarizer 40 each having a regionally-varying transmittance includes: manufacturing a single first polarizer 40 including a polarizing film 401.

In some other embodiments, manufacturing the at least one first polarizer 40 each having a regionally-varying transmittance includes: manufacturing a single first polarizers 40 including two layers of polarizing films 401 stacked one on another.

In some other embodiments, manufacturing the at least one first polarizer 40 each having a regionally-varying transmittance includes: manufacturing two first polarizers 40 stacked one on another. Each of the first polarizers 40 includes a polarizing film 401.

When manufacturing the polarizing film 401, the transmittance of different regions of the polarizing film 401 is controlled according to requirements on the transmittance of each region. For example, when using a stretching technique to manufacture a polarizing film, it will be assured that different regions have different transmittances by controlling the stretching technique.

In the case where the regional division of the luminance of the display panel 10 is relatively simple, and it is technically possible to make a polarizing film 401 having a corresponding transmittance in each of corresponding regions, then the first polarizer 40 include for example only one polarizing film 401. In the case where the regional division of the luminance of the display panel 10 is relatively complicated, and it is technically impossible to make a polarizing film 401 have a corresponding transmittance in each of corresponding regions, then the first polarizer 40 includes for example two layers of polarizing films 401, or two first polarizers 40 may be made, with each of the first polarizers 40 including a polarizing film 401. By properly dividing each polarizing film 401 into regions and setting the transmittances of each region, the transmittance of the first polarizer 40 may be made to vary regionally, and the regions of the first polarizer 40 are in one-to-one correspondence with the regions of the display panel 10 divided according to luminance.

In some embodiments, forming a transmittance adjusting structure 20 on a light exit side of the display panel 10 includes: manufacturing a second polarizer 30 having a uniform transmittance and a film layer 60 having a regionally-varying transmittance that is in contact with the second polarizer and is disposed on one side of the second polarizer, and attaching the second polarizer 30 and the film layer 60 having a regionally-varying transmittance to the light exit side of the display panel 10.

That is, the transmittance adjusting structure 20 is manufactured based on the second polarizer 30 having a uniform transmittance. In some embodiments, the method for manufacturing the second polarizer 30 having a uniform transmittance includes: laminating one roll of polarizer having a uniform transmittance at a time, and cutting the roll of polarizer into corresponding sizes as needed to obtain second polarizers 30 each having a uniform transmittance. Then a film layer 60 having a regionally varying transmittance is manufactured on the second polarizer 30 of a corresponding size, so that the finished transmittance adjusting structure 20 has different transmittances in different regions. In some embodiments, the film layer 60 having a regionally-varying transmittance is manufactured through ink printing.

The foregoing descriptions are merely some embodiments of the present disclosure, but the protection scope of the present disclosure is not limited thereto. Any variation or replacement easily conceivable by those skilled in the art in the technical scope disclosed by the present disclosure shall fall in the protection scope of the present disclosure. Therefore, the protection scope of the present disclosure should be subject to the protection scope of the claims.

What is claimed is:

1. A display module, comprising:
a display panel; and
a transmittance adjusting structure disposed on a light exit side of the display panel, wherein a transmittance of the transmittance adjusting structure varies regionally in accordance with a regional distribution law of a display luminance of the display panel.

2. The display module according to claim 1, wherein the transmittance adjusting structure comprises at least one first polarizer and each first polarizer has a regionally-varying transmittance.

3. The display module according to claim 2, wherein the transmittance adjusting structure comprises a single first polarizer, and the first polarizer comprises a polarizing film.

4. The display module according to claim 2, wherein the transmittance adjusting structure comprises a single first polarizer, and the first polarizer comprises two layers of polarizing films stacked one on another.

5. The display module according to claim 2, wherein the transmittance adjusting structure includes two first polarizers stacked one on another, and each of the two first polarizers comprises a polarizing film.

6. The display module according to claim 1, wherein the transmittance adjusting structure comprises a second polarizer having a uniform transmittance and a film layer having a regionally-varying transmittance, and the film layer and the second polarizer are stacked one on another.

7. The display module according to claim 1, wherein the display panel comprises an array substrate and an encapsulating substrate; the array substrate comprises OLED components, and each OLED component is disposed in a corresponding one of pixel units.

8. The display module according to claim 7, wherein the OLED components are of a top light-emitting type; and
the transmittance adjusting structure is disposed on a side of the encapsulating substrate facing the array substrate, or disposed on a side of the encapsulating substrate facing away from the array substrate.

9. The display module according to claim 7, wherein the OLED components are of a bottom light-emitting type; and
the transmittance adjusting structure is disposed on a side of the array substrate facing away from the package substrate.

10. The display module according to claim 1, wherein the display panel comprises an array substrate, an assembling substrate, and a liquid crystal layer disposed therebetween.

11. The display module according to claim 2, wherein the display panel comprises an array substrate, an assembling substrate, and a liquid crystal layer disposed therebetween; the transmittance adjusting structure is disposed on a side of the assembling substrate facing away from the array substrate; and
the display module further comprises a lower polarizer disposed on a side of the array substrate facing away from the assembling substrate, and the lower polarizer has a uniform transmittance.

12. The display module according to claim 6, wherein the display panel comprises an array substrate, an assembling substrate, and a liquid crystal layer disposed therebetween; the transmittance adjusting structure is disposed on a side of the assembling substrate facing away from the array substrate;
the display module further comprises a lower polarizer disposed on a side of the array substrate facing away from the assembling substrate, and the lower polarizer has a uniform transmittance.

13. A display device, comprising the display module according to claim 1.

14. A method of manufacturing the display module according to claim 1, comprising:
manufacturing a display panel; and
forming a transmittance adjusting structure on a light exit side of the display panel, wherein
a transmittance of the transmittance adjusting structure varies regionally in accordance with a regional distribution law of a display luminance of the display panel.

15. The method of manufacturing the display module according to claim 14, wherein forming the transmittance adjusting structure on the light exit side of the display panel comprises:
manufacturing at least one first polarizer each having a regionally-varying transmittance, and attaching the at least one first polarizer to the light exit side of the display panel; or,
manufacturing a second polarizer having a uniform transmittance and a film layer having a regionally-varying transmittance that is in contact with the second polarizer and is disposed on one side of the second polarizer, and attaching the second polarizer and the film layer to the light exit side of the display panel.

16. The method of manufacturing the display module according to claim 15, wherein manufacturing the at least one first polarizer each having a regionally-varying transmittance comprises:
manufacturing a single first polarizer, wherein the first polarizer comprises a polarizing film; or
manufacturing a single first polarizer, wherein the first polarizer comprises two layers of polarizing films that are stacked one on another; or
manufacturing two first polarizers, wherein the two first polarizers are stacked one on another, and each of the two first polarizers comprises a polarizing film.
